(19) United States
(12) Patent Application Publication
(10) Pub. No.: US 2025/0297365 A1
(43) Pub. Date: Sep. 25, 2025

(54) ILLUMINATION DEVICE FOR FILM GROWTH PROCESS AND FILM GROWTH PROCESS EQUIPMENT

(71) Applicant: National Tsing Hua University, Hsinchu City (TW)

(72) Inventors: Po-Wen Chiu, Hsinchu City (TW); Jui-Kang Yen, Hsinchu City (TW)

(73) Assignee: National Tsing Hua University, Hsinchu City (TW)

(21) Appl. No.: 18/634,980

(22) Filed: Apr. 14, 2024

(30) Foreign Application Priority Data
Mar. 20, 2024 (TW) 113110229

(51) Int. Cl. C23C 16/48

(52) U.S. Cl. CPC C23C 16/488

(57) ABSTRACT

A film growth process equipment including a main chamber and an illumination device is provided. The illumination device includes a light source, a transparent layer, and a van der Waals material layer. The transparent layer includes a light-emitting surface away from the light source. The van der Waals material layer has a defect concentration lower than 10¹² cm⁻², and is disposed on the light-emitting surface of the transparent layer. The van der Waals material layer is formed as a portion of an inner surface of the main chamber.

### CROSS-REFERENCE TO RELATED APPLICATION

This application claims the priority benefit of Taiwan application serial no. 113110229, filed on Mar. 20, 2024. The entirety of the above-mentioned patent application is hereby incorporated by reference herein and made a part of this specification.

### BACKGROUND

### Technical Field

The disclosure relates to an illumination device for film growth process and a film growth process equipment.

### Description of Related Art

In a process using atomic layer deposition (ALD), physical vapor deposition (PVD) or other similar process methods, reactants that are not completely removed may deposit in multiple parts of a chamber, causing contamination. In some processes that require photocatalysis, activation or heating of reactants, a light-emitting surface of an illumination device may decrease in light-emitting quality due to contamination.

### SUMMARY

The disclosure is directed to an illumination device for film growth process and a film growth process equipment, which avoids contamination of a light-emitting surface of the illumination device and improve a service life of the film growth process equipment.

An embodiment of the disclosure provides an illumination device for film growth process including a light source, a transparent layer, and a van der Waals material layer. The transparent layer includes a light-emitting surface away from the light source. The van der Waals material layer has a defect concentration lower than 10¹² cm⁻², and is disposed on the light-emitting surface of the transparent layer.

An embodiment of the disclosure provides a film growth process equipment including a main chamber and an illumination device. The illumination device includes a light source, a transparent layer, and a van der Waals material layer. The transparent layer includes a light-emitting surface away from the light source. The van der Waals material layer has a defect concentration lower than 10¹² cm⁻², and is disposed on the light-emitting surface of the transparent layer. The van der Waals material layer is formed as a portion of an inner surface of the main chamber.

Based on the above descriptions, the illumination device provided by the embodiment of the disclosure is provided with a van der Waals material layer on its light-emitting surface. By using the characteristic of the van der Waals material layer having no dangling bonds, the illumination device is adapted for catalyzing, activating or heating reactants during the film growth process, and avoids contamination caused by the reactants in the process being deposited on the light-emitting surface of the illumination device, thereby increasing a service life of the film growth process equipment.

To make the aforementioned more comprehensible, several embodiments accompanied with drawings are described in detail as follows.

### BRIEF DESCRIPTION OF THE DRAWINGS

FIG. 1 is a schematic diagram of a film growth process equipment according to an embodiment of the disclosure.

FIG. 2, FIG. 3, FIG. 4, FIG. 5, FIG. 6, and FIG. 7 are respectively schematic diagrams of illumination devices for film growth process according to embodiments of the disclosure.

FIG. 8 is a schematic diagram of a film growth process equipment according to an embodiment of the disclosure.

### DESCRIPTION OF THE EMBODIMENTS

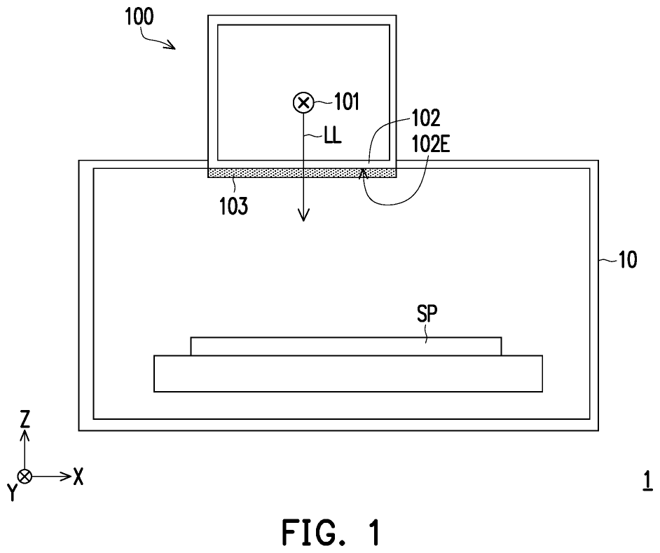

Referring to FIG. 1, FIG. 1 is a schematic diagram of a film growth process equipment according to an embodiment of the disclosure. The film growth process equipment 1 includes a main chamber 10 and an illumination device 100, which is adapted for using atomic layer deposition (ALD), physical vapor deposition (PVD) or other similar process methods to grow a film on a substrate SP or on a layer structure on the substrate SP.

The illumination device 100 includes a light source 101, a transparent layer 102, and a van der Waals material layer 103. The light source 101 is configured to provide a light beam LL to catalyze, activate or heat reactants in a process, or to reduce or eliminate defective structures of the film. The light beam LL may be infrared light with a main band wavelength between 800 nm and 3000 nm, visible light with a main band wavelength between 400 nm and 800 nm, ultraviolet light with a main band wavelength between 140 nm and 400 nm, or microwave with a main band wavelength between 1 mm and 1 m, but the disclosure is not limited thereto. In some non-illustrated embodiments, the light source 101 may include a plurality of sub-light sources, and the sub-light sources respectively emit light beams with different main wavelength bands.

The transparent layer 102 may be implemented by transparent glass and includes a light-emitting surface 102E. The van der Waals material layer 103 disposed on the light-emitting surface 102E is formed as a portion of an inner surface of the main chamber 10. A defect concentration of the van der Waals material layer 103 is lower than 10¹² cm⁻², and there are no unbonded dangling bonds. Accordingly, it may prevent reactants in the deposition process from being deposited on the light-emitting surface 102E of the transparent layer 102 and avoid a decrease of transmittance of the transparent layer 102. The Van der Waals material layer 103 may include one of graphene, boron nitride, transition metal chalcogenides, or van der Waals bonding materials with a layered structure. Furthermore, the van der Waals material layer 103 may be formed as a single layer or a plurality of layers, such as 2 layers, 3 layers, 4 layers or 5 layers.

In order to fully illustrate various implementation aspects of the disclosure, other embodiments of the disclosure will be described below. It must be noted here that the following embodiments follow the component numbers and part of the content of the previous embodiments, where the same numbers are used to represent the same or similar elements, and descriptions of the same technical content are omitted. For descriptions of the omitted parts, reference may be made to the foregoing embodiments, which will not be repeated in the following embodiments.

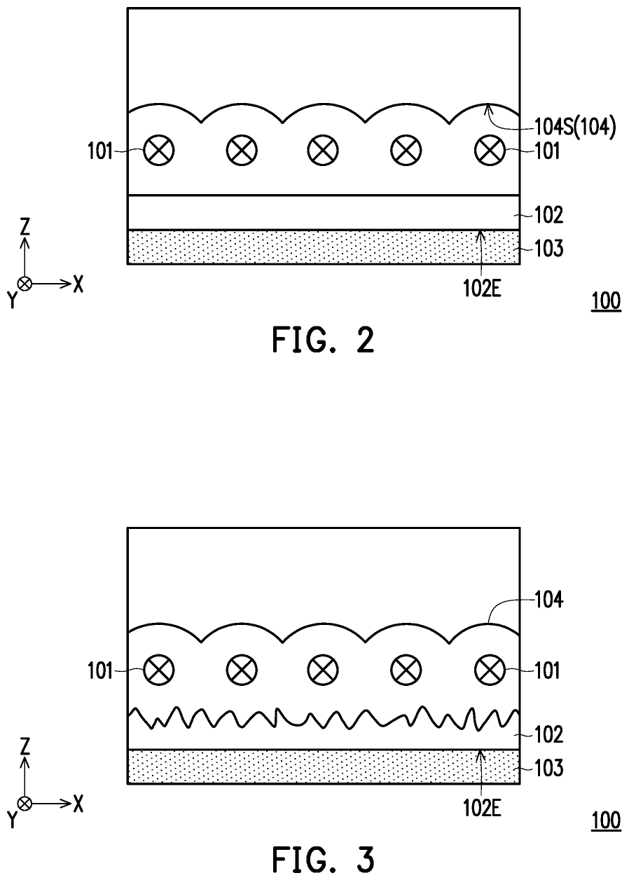

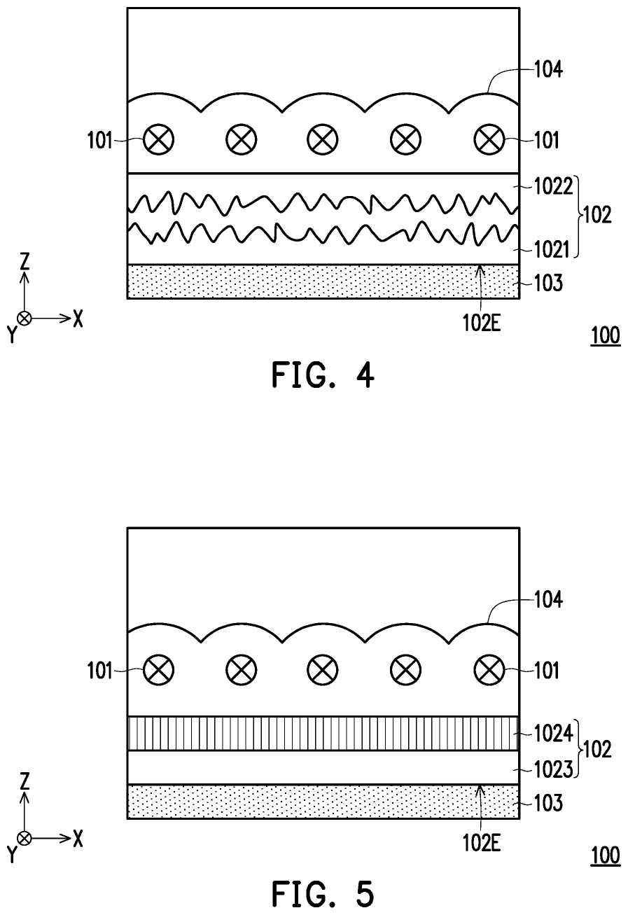

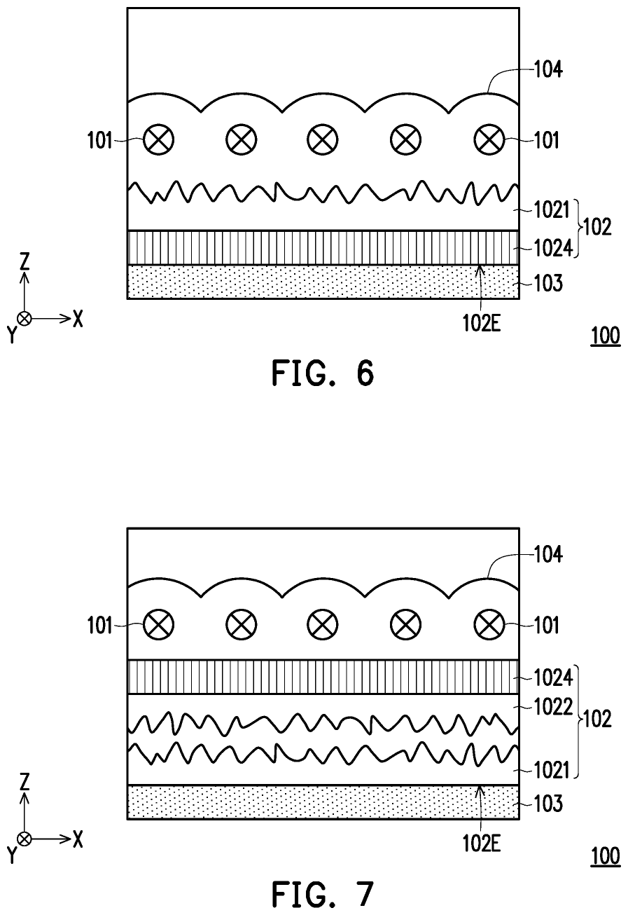

Referring to FIG. 2, FIG. 3, FIG. 4, FIG. 5, FIG. 6, and FIG. 7 together with FIG. 1, which respectively illustrate alternatives to the illumination device 100 in FIG. 1.

Refer to FIG. 1 and FIG. 2, in the embodiment, the illumination device 100 includes the light source 101, the transparent layer 102, the van der Waals material layer 103, and a light reflective layer 104. The light source 101 may include a laser, an excimer lamp, a light-emitting diode, a xenon-containing lamp, a krypton-containing lamp, a mercury vapor lamp, a metal-halide lamp, a deuterium lamp, etc. The light source 101 may be arranged in an array, and may provide continuous irradiation or intermittent pulse irradiation. The laser light source may be a continuous-wave laser or a pulse laser that provides intermittent pulse irradiation. The light beam LL provided by the light source 101 may be parallel light. The light reflective layer 104 has a reflective surface 104S facing the light source 101. The light reflective layer 104 is configured to reflect the light beam LL generated by the light source 101, so that the light beam LL travels toward the transparent layer 102, exits the illumination device 100 from the light-emitting surface 102E, and enters the interior of the main chamber 10. The light reflective layer 104 may be, for example, implemented by a light collecting plate, but the disclosure is not limited thereto.

Referring to FIG. 1 and FIG. 3, in the embodiment, the illumination device 100 includes the light source 101, the transparent layer 102, the van der Waals material layer 103, and the light reflective layer 104. The transparent layer 102 may be made of transparent glass, and a surface of the transparent glass facing the light source 101 is ground to form a light scattering layer. Accordingly, the light beam LL emitted by the light source 101 may be homogenized and then enter the interior of the main chamber 10.

Referring to FIG. 1 and FIG. 4, in the embodiment, the illumination device 100 includes the light source 101, the transparent layer 102, the van der Waals material layer 103, and the light reflective layer 104. The transparent layer 102 includes a light scattering layer 1021 and a light scattering layer 1022. The light scattering layer 1021 may be made of a transparent material, and its surface facing the light source 101 is ground and atomized, thus having a scattering function. The light scattering layer 1022 may be made of a transparent material, and its surface away from the light source 101 is ground and atomized, thus having the scattering function. The light scattering layer 1022 may also be a fly-eye lens array with the scattering function. Accordingly, the light beam LL emitted by the light source 101 may be homogenized and then enter the interior of the main chamber 10.

Referring to FIG. 1 and FIG. 5, in the embodiment, the illumination device 100 includes the light source 101, the transparent layer 102, the van der Waals material layer 103, and the light reflective layer 104. The transparent layer 102 includes a transparent glass layer 1023 and an electrochromic layer 1024. By controlling a transmittance of the electrochromic layer 1024, an intensity of the light beam LL entering the interior of the main chamber 10 may be controlled.

Refer to FIG. 1 and FIG. 6, in the embodiment, the illumination device 100 includes the light source 101, the transparent layer 102, the van der Waals material layer 103, and the light reflective layer 104. The transparent layer 102 includes the light scattering layer 1021 and the electrochromic layer 1024. The light scattering layer 1021 may be made of transparent glass, and its surface facing the light source 101 is ground, thus having the scattering function. By controlling the transmittance of the electrochromic layer 1024, the intensity of the light beam LL entering the interior of the main chamber 10 may be controlled.

Refer to FIG. 1 and FIG. 7, in the embodiment, the illumination device 100 includes the light source 101, the transparent layer 102, the van der Waals material layer 103, and the light reflective layer 104. The transparent layer 102 includes the light scattering layer 1021, the light scattering layer 1022 and the electrochromic layer 1024. The light scattering layer 1021 may be made of transparent glass, and its surface facing the light source 101 is ground, thus having the scattering function. The light scattering layer 1022 may be made of transparent glass, and its surface away from the light source 101 is ground, thus having the scattering function. By controlling the transmittance of the electrochromic layer 1024, the intensity of the light beam LL entering the interior of the main chamber 10 may be controlled.

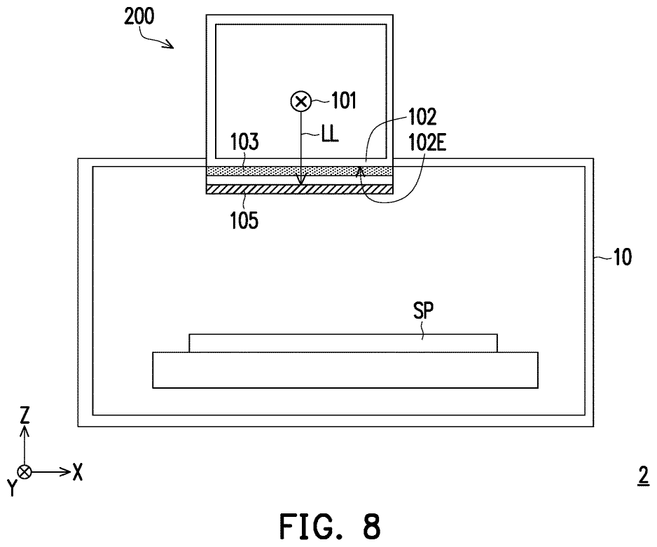

Referring to FIG. 8, FIG. 8 is a schematic diagram of a film growth process equipment according to an embodiment of the disclosure. A film growth process equipment 2 includes a main chamber 10 and an illumination device 200. The illumination device 200 is different from the illumination device 100 shown in FIG. 1 in that it further includes a light shielding plate 105, where after the light beam LL generated by the light source 101 passes through the van der Waals material layer 103, the light shielding plate 105 is disposed on the path of the light beam LL as shown in FIG. 8 such that the light beam LL cannot enter the main chamber 10, or the light shielding plate 105 may be removed from the path of the light beam LL so that the light beam LL may enter the main chamber 10.

In summary, the illumination device provided by the embodiment of the disclosure is provided with a van der Waals material layer on its light-emitting surface. By using the characteristic of the van der Waals material layer having no dangling bonds, the illumination device is adapted for catalyzing, activating or heating reactants during the film growth process, and avoids contamination caused by the reactants in the process being deposited on the light-emitting surface of the illumination device, thereby increasing a service life of the film growth process equipment.

1. An illumination device for film growth process, comprising:
a light source;
a transparent layer, wherein the transparent layer comprises a light-emitting surface away from the light source; and
a van der Waals material layer, disposed on the light-emitting surface of the transparent layer.

2. The illumination device for film growth process as claimed in claim 1, wherein the van der Waals material layer is a single layer or a plurality of layers, and comprises graphene, boron nitride, or transition metal chalcogenide.

3. The illumination device for film growth process as claimed in claim 1, wherein the film growth process comprises an atomic layer deposition (ALD) process and a physical vapor deposition (PVD) process.

4. The illumination device for film growth process as claimed in claim 1, wherein the light source comprises a laser, an excimer lamp, a light-emitting diode, a xenon-containing lamp, a krypton-containing lamp, a mercury vapor lamp, a metal-halide lamp, and a deuterium lamp.

5. The illumination device for film growth process as claimed in claim 1, wherein the light source is arranged in an array and provides continuous irradiation or intermittent pulse irradiation.

6. The illumination device for film growth process as claimed in claim 1, further comprising a light reflective layer, wherein the light source is disposed between the light reflective layer and the transparent layer, and the light reflective layer has a reflective surface facing the light source.

7. The illumination device for film growth process as claimed in claim 1, wherein the transparent layer comprises an electrochromic layer, and the illumination device for film growth process controls an intensity of light penetrating the van der Waals material layer through the electrochromic layer.

8. The illumination device for film growth process as claimed in claim 1, wherein the transparent layer comprises at least one light scattering layer.

9. The illumination device for film growth process as claimed in claim 8, wherein the at least one light scattering layer comprises an atomized transparent material and a fly-eye lens array.

10. The illumination device for film growth process as claimed in claim 1, wherein the light source is parallel light when reaching the transparent layer.

11. The illumination device for film growth process as claimed in claim 1, further comprising a light shielding plate, wherein after a light beam generated by the light source passes through the van der Waals material layer, a passage of the light beam is controlled by controlling the light shielding plate.

12. A film growth process equipment, comprising:
a main chamber; and
the illumination device for film growth process as claimed in claim 1, wherein
the van der Waals material layer is formed as a portion of an inner surface of the main chamber.

13. The film growth process equipment as claimed in claim 12, wherein the van der Waals material layer is a single layer or a plurality of layers, and comprises graphene, boron nitride, or transition metal chalcogenide.

14. The film growth process equipment as claimed in claim 12, wherein the film growth process equipment comprises an atomic layer deposition (ALD) process equipment and a physical vapor deposition (PVD) process equipment.

15. The film growth process equipment as claimed in claim 12, wherein the light source comprises a laser, an excimer lamp, a light-emitting diode, a xenon-containing lamp, a krypton-containing lamp, a mercury vapor lamp, a metal-halide lamp, and a deuterium lamp.

16. The film growth process equipment as claimed in claim 12, wherein the illumination device for film growth process further comprises a light reflective layer, the light source is disposed between the light reflective layer and the transparent layer, and the light reflective layer has a reflective surface facing the light source.

17. The film growth process equipment as claimed in claim 12, wherein the transparent layer comprises an electrochromic layer, and the illumination device for film growth process controls an intensity of light penetrating the van der Waals material layer through the electrochromic layer.

18. The film growth process equipment as claimed in claim 12, wherein the transparent layer comprises at least one light scattering layer.

19. The film growth process equipment as claimed in claim 12, wherein the light source is parallel light when reaching the transparent layer.

20. The film growth process equipment as claimed in claim 12, wherein the light source is arranged in an array and provides continuous irradiation or intermittent pulse irradiation.
